(19) United States
(12) Patent Application Publication
(10) Pub. No.: US 2023/0311791 A1
(43) Pub. Date: Oct. 5, 2023

(54) ELECTRONIC CONTROL DEVICE

(71) Applicant: HITACHI ASTEMO, LTD., Hitachinaka-shi, Ibaraki (JP)

(72) Inventor: Kentaro YAMANAKA, Hitachinaka-shi, Ibaraki (JP)

(73) Assignee: HITACHI ASTEMO, LTD., Hitachinaka-shi, Ibaraki (JP)

(21) Appl. No.: 18/044,006

(22) PCT Filed: Jun. 29, 2021
(86) PCT No.: PCT/JP2021/024485

§ 371 Date: Mar. 3, 2023

(30) Foreign Application Priority Data
Nov. 4, 2020 (JP) 2020-184324

(51) Int. Cl. B60R 16/023; H05K 5/00

(52) U.S. Cl. CPC B60R 16/0239; H05K 5/0052; H05K 5/0069; H05K 5/006

(57) ABSTRACT

An electronic control device 10 includes a circuit board 13 and first and second members 14, 15. Various electronic components are mounted on the circuit board. The first member has the circuit board attached thereto, and has a groove 14a in the periphery of an attachment part for the circuit board. The second member has a protrusion 15a to be placed in the groove. The groove and the protrusion are joined with first adhesive to form an internal space and a casing that accommodates the circuit board. Retention parts 18-1,18-2 that retain excess adhesive are provided in the groove in the first member. Each of the retention parts opens into an inner side wall of the groove.

### TECHNICAL FIELD

The present invention relates to an electronic control device in which a base member and a cover are adhered at peripheries thereof with waterproof adhesive to form a casing, and a circuit board on which various electronic components are mounted is accommodated in the casing.

### BACKGROUND ART

Conventionally, in this type of an electronic control device, as described in Patent Document 1, for example, a casing is formed by putting a protrusion formed in a peripheral edge part of a second case (cover) into a groove formed in a peripheral edge part of a first case (base member) with sealing material. Then, a circuit board on which electronic components are mounted is accommodated in an internal space of the casing.

### REFERENCE DOCUMENT LIST

### Patent Document

Patent Document 1: JP 6347194 B2

### SUMMARY OF THE INVENTION

### Problem to be Solved by the Invention

In the above Patent Document 1, when joining the first case with the second case, a plurality of through holes communicating with the outside is formed in a groove bottom surface to prevent generation of an enclosed space between the sealing material and a wall surface of the groove. However, with such a configuration, moisture and salt penetrating through the through holes may cause corrosion and rust in the cases, enter into the casing, and the waterproofing structure for the electronic components and the circuit board is not established.

The present invention has been made in view of the foregoing and aims to provide an electronic control device that can reduce deterioration of electronic components and a circuit board accommodated in a casing.

### Means for Solving the Problem

According to an aspect of the present invention, provided is an electronic control device including: a circuit board on which an electronic component is mounted; a first member to which the circuit board is attached and having a groove in a periphery of an attachment part for the circuit board; and a second member having a protrusion to be placed in the groove, the groove in the first member and the protrusion of the second member being joined with first adhesive to form an internal space and a casing that accommodates the circuit board, in which the electronic control device comprises a retention part that opens into the groove in the first member and retains excess first adhesive.

### Effects of the Invention

According to the present invention, since the retention part allows inflow and retention of excess adhesive, there is no need to provide a through hole communicating with the outside. As a result, occurrence of corrosion and rust in the first member is reduced, and a waterproof structure for the electronic components and the circuit board accommodated in the casing can be established. Accordingly, it is possible to provide an electronic control device that can reduce deterioration of electronic components and a circuit board accommodated in a casing.

### BRIEF DESCRIPTION OF THE DRAWINGS

FIG. 1 is an exploded perspective view of an electronic control device according to an embodiment of the present invention.

FIG. 2 is a plan view of the electronic control device according to the embodiment of the present invention.

FIG. 3 is a side view of the electronic control device according to the embodiment of the present invention.

FIG. 4 is a front view of the electronic control device according to the embodiment of the present invention.

FIG. 5A is a plan view of a base member of an electronic control device according to a first embodiment of the present invention.

FIG. 5B is a side view of the base member of the electronic control device according to the first embodiment of the present invention.

FIG. 5C is a front view of the base member of the electronic control device according to the first embodiment of the present invention.

FIG. 6 is a perspective view of the base member of the electronic control device according to the first embodiment of the present invention.

FIG. 7A is a perspective view for describing the vicinity of a first retention part of the base member illustrated in FIG. 6.

FIG. 7B is an enlarged perspective view of a region surrounded by a chain double-dashed line in FIG. 7A.

FIG. 8A is a perspective view for describing the vicinity of a second retention part of the base member illustrated in FIG. 6.

FIG. 8B is an enlarged perspective view of a region surrounded by a chain double-dashed line in FIG. 8A.

FIG. 9 is a perspective view illustrating a process of applying waterproof adhesive on the base member illustrated in FIG. 6.

FIG. 10 is a perspective view illustrating a process of attaching a circuit board and a connector to the base member illustrated in FIG. 9.

FIG. 11 is a perspective view illustrating a process of attaching a cover to the base member illustrated in FIG. 10.

FIG. 12 is an enlarged cross-sectional view of the vicinity of a retention part of FIG. 11.

FIG. 13 is an enlarged perspective view of the vicinity of a retention part of a base member of an electronic control device according to a second embodiment of the present invention.

FIG. 14 is an enlarged perspective view of the vicinity of a first retention part of a base member of an electronic control device according to a third embodiment of the present invention.

FIG. 15 is an enlarged perspective view of the vicinity of a second retention part of the base member of the electronic control device according to the third embodiment of the present invention.

### MODE FOR CARRYING OUT THE INVENTION

Hereinafter, embodiments of the present invention will be described with reference to the drawings.

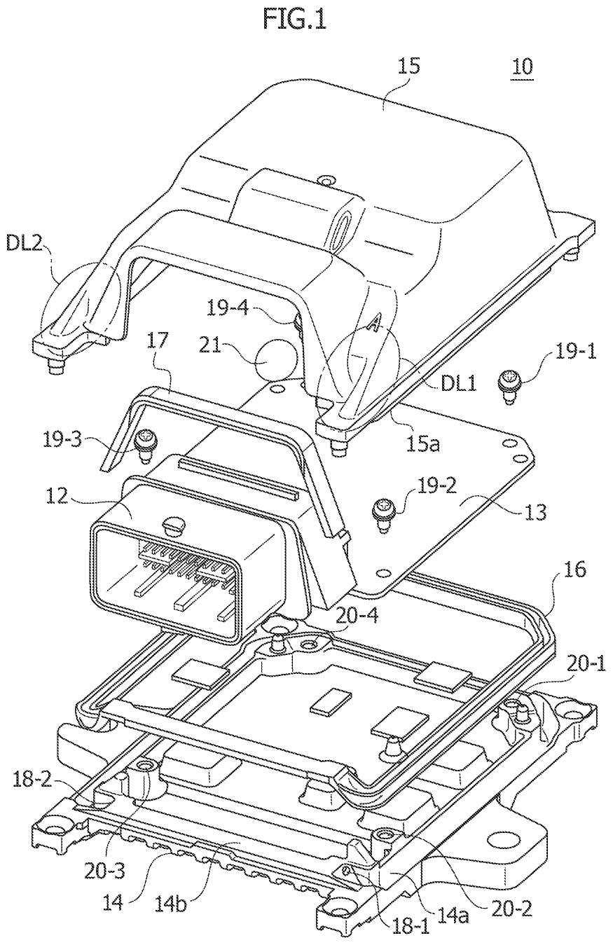

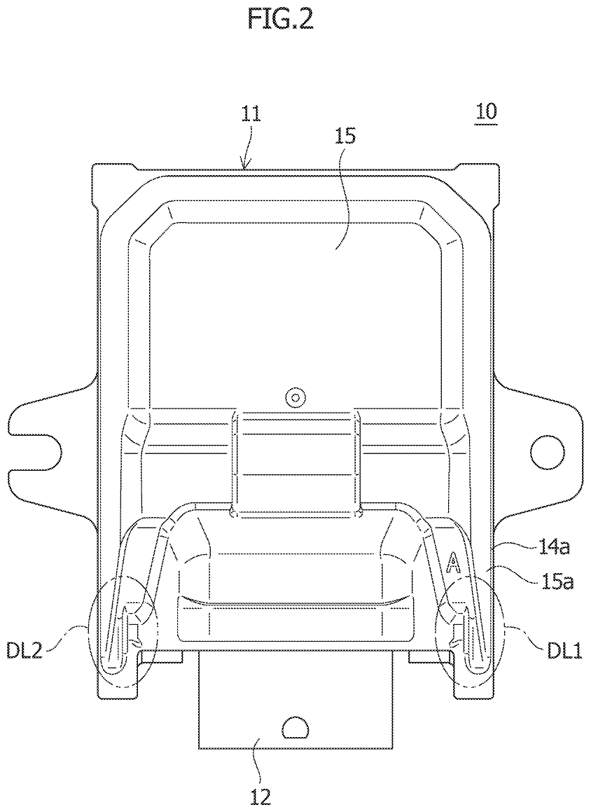

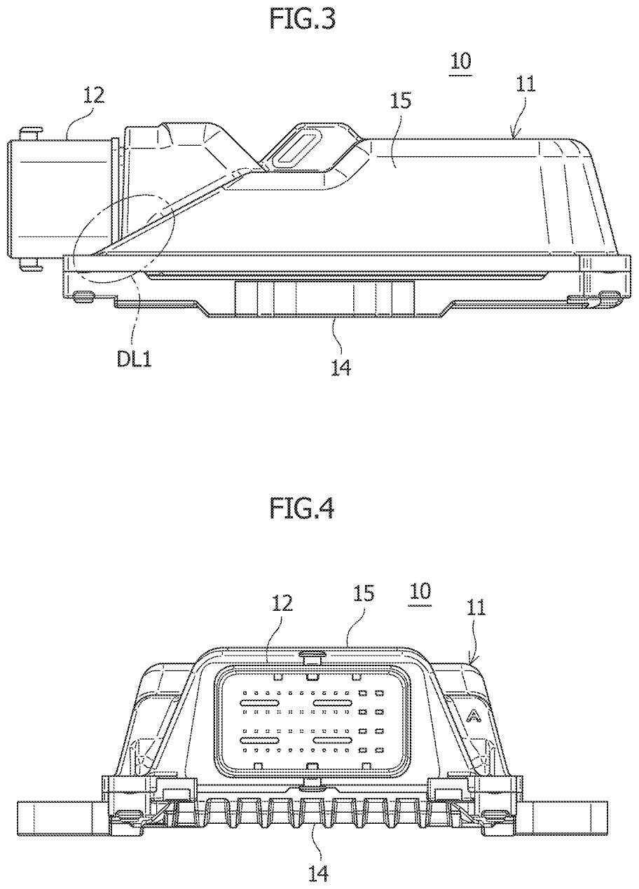

FIG. 1 is an exploded perspective view of an electronic control device according to an embodiment of the present invention, FIG. 2 is a plan view of the electronic control device, FIG. 3 is a side view thereof, and FIG. 4 is a front view thereof. An electronic control device 10 has a waterproof structure, and is installed in an engine compartment of a vehicle, for example. Electronic control device 10 controls an engine, a transmission, a brake, and the like according to a driving operation by the driver, a vehicle state, and the surrounding environment.

As illustrated in FIGS. 1 to 4, electronic control device 10 includes a casing 11, and a plate-shaped circuit board 13 on which various electronic components (not illustrated) are mounted and to which a connector 12 is attached. Casing 11 is formed by joining a base member (first member) 14 and a resin cover (second member) 15 with waterproof adhesive 16, 17 as sealing material interposed therebetween. Waterproof adhesive (first adhesive) 16 is applied on the inside of a groove 14a formed in a peripheral edge part of base member 14 and an attachment part 14b for connector 12 to adhere and join base member 14 with cover 15 and base member 14 with connector 12.

Additionally, waterproof adhesive (second adhesive) 17 is applied along an outer peripheral part of connector 12, except for a joining part with base member 14, to adhere and join connector 12 with cover 15. Bottomed holes (retention parts) 18-1,18-2 that allow inflow and retention of excess adhesive are provided in groove 14a of base member 14 in a region (a region called a three-way intersection, surrounded by chain double-dashed line DL1, DL2) below a tilted surface of connector 12 at which waterproof adhesive 16 and waterproof adhesive 17 come together. Each of bottomed holes 18-1,18-2 opens into groove 14a.

As described above, waterproof casing 11 accommodating circuit board 13 is formed by combining base member 14 and cover 15 with waterproof adhesive 16,17 and to enclose the internal space.

Circuit board 13 is attached to pedestals 20-1 to 20-4 of base member 14 with screws 19-1 to 19-4, and the entire circuit board 13 is accommodated in the internal space formed by base member 14 and cover 15. Although not shown, various electronic components such as a microcomputer, a power transistor, a resistor, and a capacitor formed of an IC, an LSI, or the like are mounted on one or both sides of circuit board 13. Additionally, connector 12 having a plurality of pins is installed in one end part of circuit board 13 so as to be sandwiched between base member 14 and cover 15 and exposing a connection part. Connector 12 is configured to electrically connect the various electronic components and circuits mounted on circuit board 13 with devices outside casing 11, and is connected to an external connector to receive power and transmit and receive various signals.

Note that a ventilation filter 21 is provided in cover 15. Ventilation filter 21 is configured to ensure ventilation and prevent entry of water and dust into casing 11 while maintaining a pressure adjustment function.

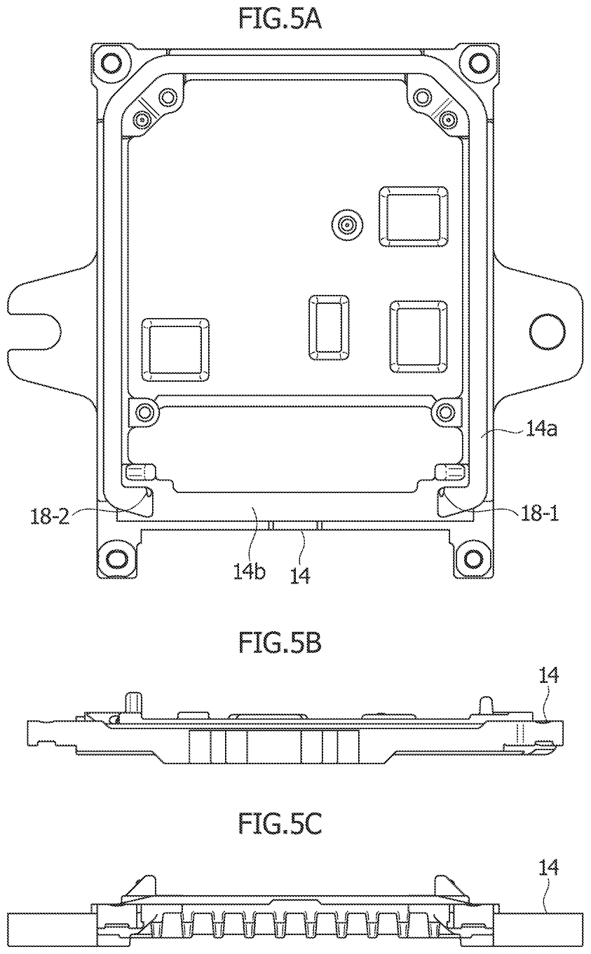

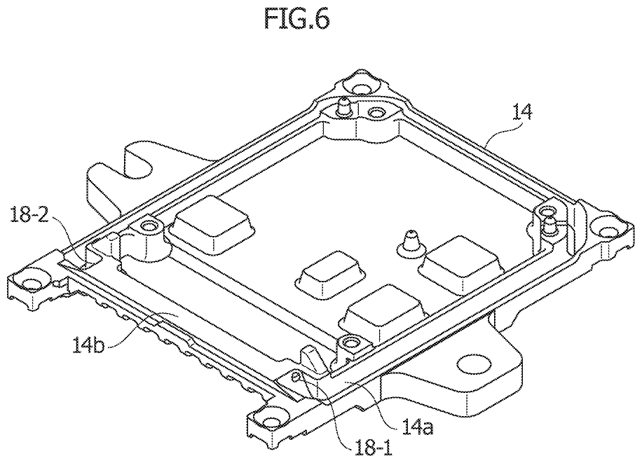

FIGS. 5A to 5C are a plan view, a side view, and a front view, respectively, of base member 14 of the electronic control device according to a first embodiment of the present invention. FIG. 6 is a perspective view of base member 14. Groove 14a on which waterproof adhesive 16 is applied is formed in the periphery of an attachment part for circuit board 13 of base member 14, which is the peripheral edge part of base member 14 in this example. Bottomed holes (retention parts) 18-1,18-2 are provided in groove 14a at positions corresponding to regions (three-way intersections) below tilted surfaces of connector 12. Bottomed holes 18-1,18-2 function as retention parts that allow inflow and retention of excess waterproof adhesive.

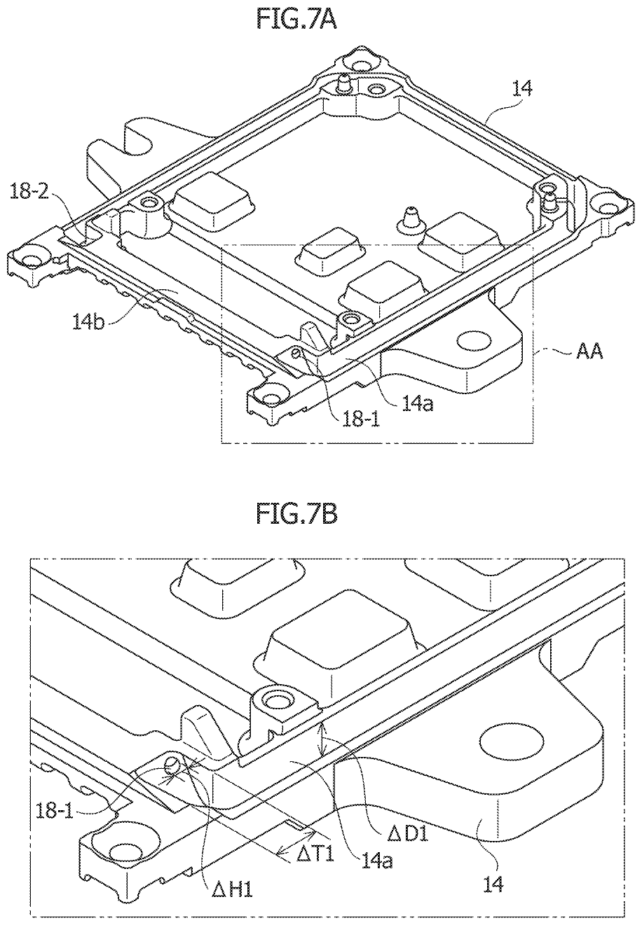

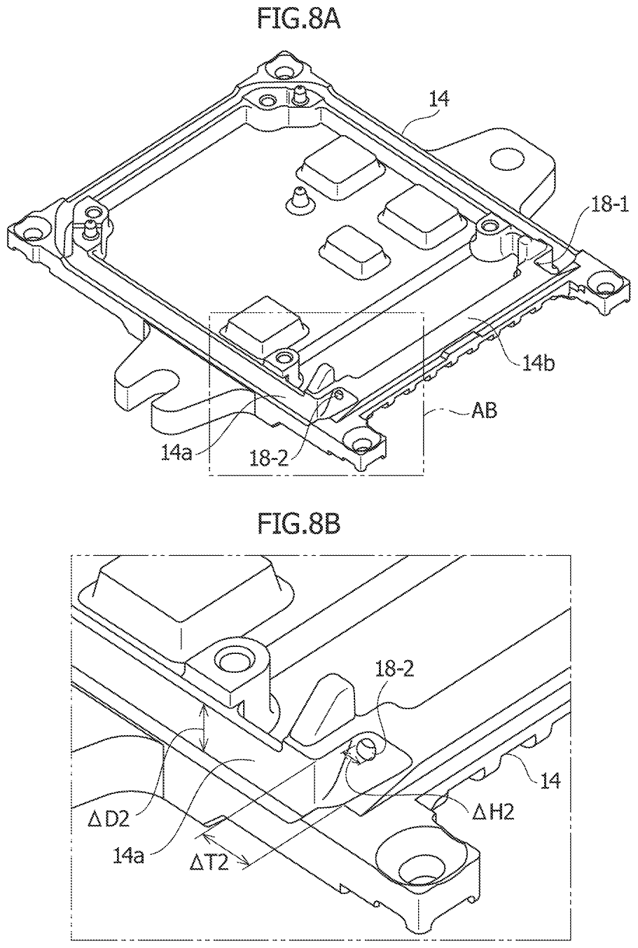

FIGS. 7A and 7B illustrate an enlargement of the vicinity of a first retention part (bottomed hole 18-1) in base member 14 illustrated in FIG. 6. FIG. 7A is a perspective view of base member 14, and FIG. 7B is an enlarged perspective view of a region surrounded by a chain double-dashed line AA in FIG. 7A. Additionally, FIGS. 8A and 8B illustrate an enlargement of the vicinity of a second retention part (bottomed hole 18-2) in base member 14 also illustrated in FIG. 6. FIG. 8A is a perspective view of base member 14, and FIG. 8B is an enlarged perspective view of a region surrounded by a chain double-dashed line AB in FIG. 8A.

As illustrated in FIG. 7B, bottomed hole 18-1 opens into an inner (inward of outer edge part of base member 14) side wall of groove 14a. The diameter ΔH1 of an opening of bottomed hole 18-1 is smaller than the width ΔT1 of groove 14a. Additionally, bottomed hole 18-1 is formed deeper than the depth ΔD1 of groove 14a.

Similarly, as illustrated in FIG. 8B, bottomed hole 18-2 opens into an inner (inward of outer edge part of base member 14) side wall of groove 14a. The diameter ΔH2 of an opening of bottomed hole 18-2 is smaller than the width ΔT2 (=ΔT1) of groove 14a. Additionally, bottomed hole 18-2 is formed deeper than the depth ΔD2 (=ΔD1) of groove 14a.

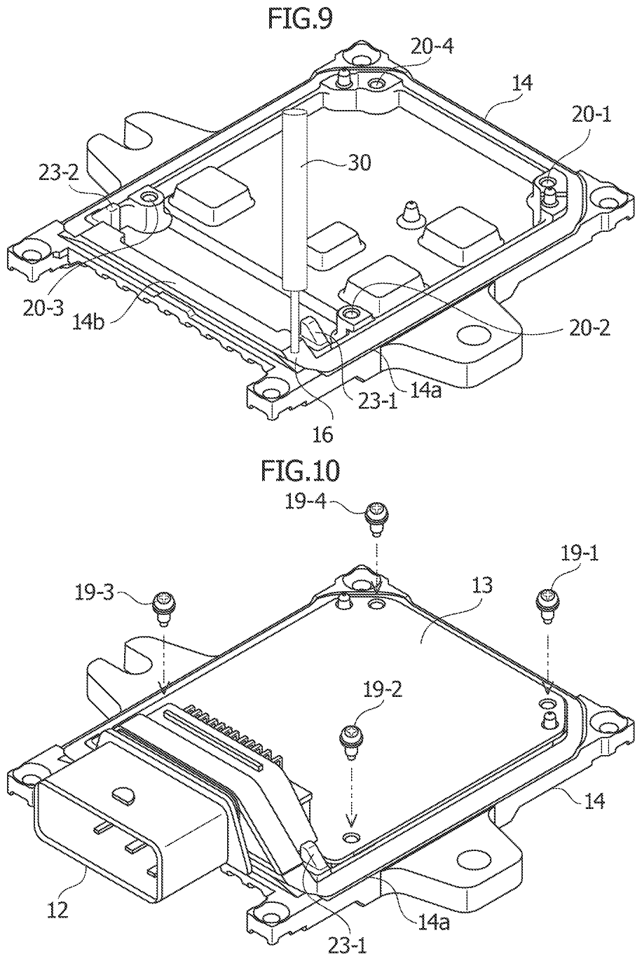

Each of FIGS. 9 to 11 illustrates a part of an assembly process of the electronic control device 10 described above. FIG. 9 illustrates a process of applying waterproof adhesive 16 on base member 14, in which waterproof adhesive 16 is applied on the inside of groove 14a and attachment part 14b for connector 12 by discharging waterproof adhesive 16 from a nozzle 30 while moving nozzle 30 along the entire peripheral part of base member 14, that is, along the peripheral edge part of base member 14.

Next, as illustrated in FIG. 10, circuit board 13 is attached to pedestals 20-1 to 20-4 of base member 14 with screws 19-1 to 19-4, and one side surface of connector 12 is adhered and fixed to base member 14 with waterproof adhesive 16 while positioning connector 12 by stoppers 23-1,23-2 that protrude upward from a board mounting surface side of base member 14.

Thereafter, waterproof adhesive 17 is discharged from nozzle 30 and applied on an upper surface and both side surfaces of an outer peripheral part of connector 12. Then, as illustrated in FIG. 11, cover 15 is adhered to base member 14 with waterproof adhesive 16, and connector 12 and cover 15 are adhered with waterproof adhesive 17 to complete assembly of the electronic control device.

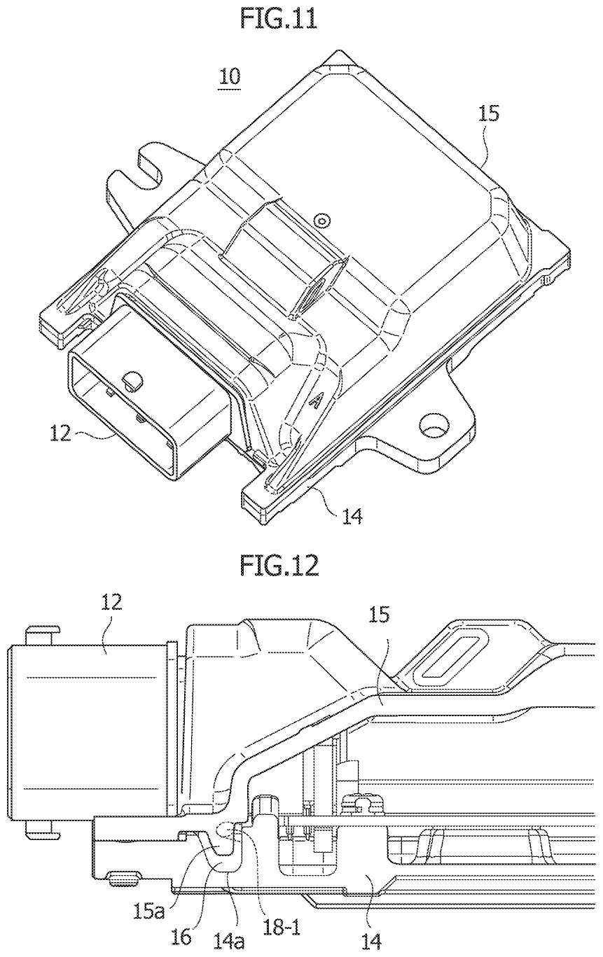

In the cover attachment process described above, as illustrated in FIG. 12, base member 14 and cover 15 are joined by placing a protrusion 15a of cover 15 in groove 14a of base member 14 to be adhered with waterproof adhesive 16 applied on the inside of groove 14a. At the time of the joining, on the region (position at which waterproof adhesive 16 and waterproof adhesive 17 come together) below the tilted surface of connector 12, the amount of adhesive is difficult to control and tends to be excessive. However, by allowing inflow and retention of excess waterproof adhesive 16 occurring in this region in retention parts 18-1,18-2, it is possible to reduce overflow of the adhesive to the outside.

In addition, since the internal space is enclosed by coupling base member 14 and cover 15, there is no through hole communicating with the outside. Hence, corrosion and rust of base member 14 can be avoided, and a waterproof structure for the electronic components and the circuit board accommodated in the casing can be established.

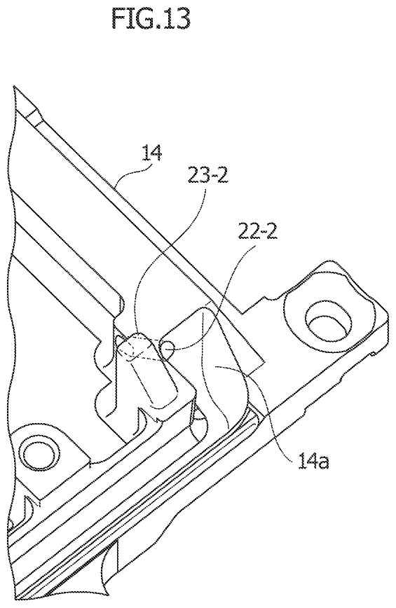

FIG. 13 is an enlarged perspective view of the vicinity of a retention part of a base member of an electronic control device according to a second embodiment of the present invention. While the retention part in the first embodiment described above is formed as bottomed holes 18-1,18-2, the retention part in the second embodiment is formed as a through hole 22-2 (although not shown, the same applies to through hole 22-1) communicating with an internal space of a casing 11. That is, through hole 22-2 penetrates a thick part of a base member 14 fixing a side surface of a connector 12 or the vicinity thereof from a side wall of a groove 14a and communicates with the internal space of casing 11.

Even with such a configuration, by allowing inflow and retention of excess adhesive in through holes 22-1,22-2, it is possible to reduce overflow of the adhesive to the outside. Furthermore, since through holes 22-1,22-2 do not communicate with the outside, it is possible to reduce deterioration of the electronic components and the circuit board accommodated in casing 11.

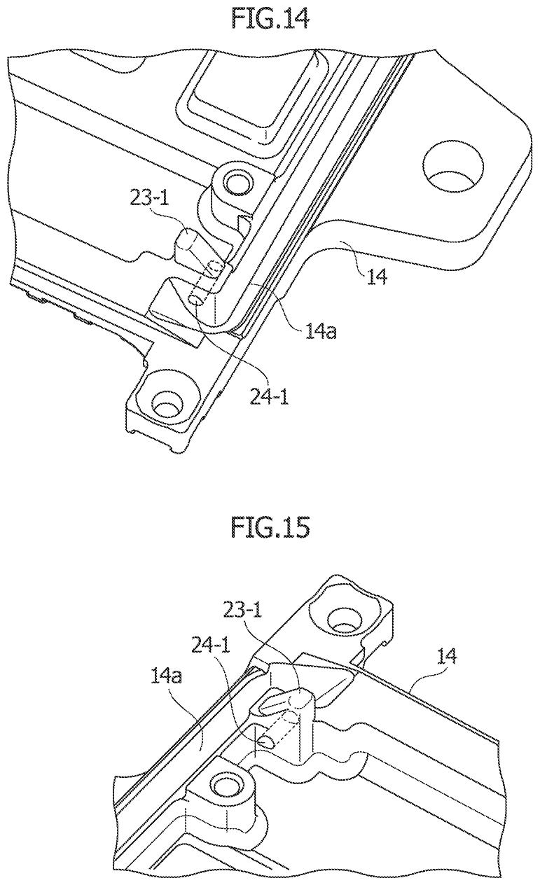

FIGS. 14 and 15 are an enlarged perspective views of the vicinity of a retention part of a base member of an electronic control device according to a third embodiment of the present invention as viewed from different directions. In the third embodiment, as in the case of the second embodiment described above, a retention part is formed as a through hole 24-1 (although not shown, the same applies to through hole 24-2) communicating with an internal space of a casing 11. That is, through hole 24-1 penetrates, from a side wall of a groove 14a, a triangular stopper 23-1 that positions and fixes a connector 12, and through hole 24-1 communicates with the internal space of casing 11.

Even with such a configuration, by allowing inflow and retention of excess adhesive in through holes 24-1,24-2, it is possible to reduce overflow of the adhesive to the outside. Furthermore, since through holes 24-1,24-2 do not communicate with the outside, it is possible to reduce deterioration of the electronic components and the circuit board accommodated in casing 11.

Note that the present invention is not limited to the first to third embodiments described above. The configurations described in the embodiments are merely schematic examples for facilitating understanding and implementation of the present invention. Accordingly, the present invention can be modified in various forms within the technical scope of the invention described in the claims.

### REFERENCE SYMBOL LIST

10 electronic control device

11 casing

12 connector

13 circuit board

14 base member (first member)

14a groove

14b attachment part for connector

15 cover (second member)

15a protrusion

16, 17 waterproof adhesive (adhesive)

18-1, 18-2 bottomed hole (retention part)

19-1 to 19-4 screw

20-1 to 20-4 pedestal

21 ventilation filter

22-1, 22-2, 24-1, 24-2 through hole (retention part)

23-1, 23-2 stopper

30 nozzle

1. An electronic control device comprising:
a circuit board on which an electronic component is mounted;
a first member to which the circuit board is attached and having a groove in a periphery of an attachment part for the circuit board; and
a second member having a protrusion to be placed in the groove,
the groove in the first member and the protrusion of the second member being joined with a first adhesive to form an internal space and a casing that accommodates the circuit board,
wherein the electronic control device comprises a retention part that opens into the groove in the first member and retains excess first adhesive.

2. The electronic control device according to claim 1, further comprising a connector which is installed to be sandwiched between the first member and the second member and which electrically connects the electronic component mounted on the circuit board with an outside of the casing, wherein
the connector is adhered to the first member with the first adhesive and is adhered to the second member with a second adhesive, and
the retention part is provided in a position at which the first adhesive and the second adhesive come together.

3. The electronic control device according to claim 1, wherein the retention part is a bottomed hole formed in the groove in the first member.

4. The electronic control device according to claim 3, wherein the retention part is smaller than a side wall of the groove.

5. The electronic control device according to claim 3, wherein the retention part is deeper than the groove.

6. The electronic control device according to claim 1, wherein the retention part is formed in the groove in the first member, and is a through hole communicating with the internal space of the casing from inside the groove.

7. The electronic control device according to claim 2, wherein:
the first member is a base member with the groove formed in the periphery of the attachment part for the circuit board, in which the first adhesive is to be applied and with the retention part provided in the groove at a position corresponding to a region below a tilted surface of the connector;
the second member is a resin cover that covers the circuit board; and
the casing is formed by joining the base member and the cover with sealing material interposed between the base member and the cover.

8. The electronic control device according to claim 7, wherein the first adhesive and the sealing material are waterproof adhesive.
